(19) United States
(12) Patent Application Publication
(10) Pub. No.: US 2015/0116874 A1
(43) Pub. Date: Apr. 30, 2015

(54) OVERVOLTAGE PROTECTION CIRCUIT

(71) Applicant: STMICROELECTRONICS (TOURS) SAS, Tours (FR)

(72) Inventors: Greca Jean Charles, Tours (FR); Bertrand Rivet, Vouvray (FR)

(73) Assignee: STMICROELECTRONICS (TOURS) SAS, Tours (FR)

(21) Appl. No.: 14/521,624

(22) Filed: Oct. 23, 2014

(30) Foreign Application Priority Data
Oct. 25, 2013 (FR) 1360438

(51) Int. Cl. H02H 9/04; H01L 27/02

(52) U.S. Cl. CPC H02H 9/04; H01L 27/0248
USPC 361/56

(57) ABSTRACT

An overvoltage protection device uses a varistor coupled in series with a switch between two terminals provided for connection to a circuit device or element to be protected. A control circuit controls actuation of the switch in response to sensing voltage at or between the two terminals in excess of a first threshold. The first threshold is less than a clipping voltage of the varistor but in excess of a supply voltage for the circuit device or element. The control circuit further controls detactuation of the switch based, for example, on elapsed time from actuation or current flow.

### PRIORITY CLAIM

This application claims the priority benefit of French Patent application number 1360438, filed on Oct. 25, 2013, the contents of which is hereby incorporated by reference in its entirety to the maximum extent allowable by law.

### TECHNICAL FIELD

The present disclosure generally relates to electronic circuits and, more specifically, to the protection of circuits or electronic components against overvoltages due, for example, to lightning.

### BACKGROUND

Electronic circuits or components are generally desired to be protected against significant and abrupt overvoltages, typically due to lightning, particularly when such circuits or components are directly connected to terminals of application of the alternating current (AC) power supply voltage delivered by the electric network.

Varistors formed of oxide and metal (MOV—“Metal Oxide Varistor”), having a resistivity which strongly drops in the presence of an abrupt voltage increase relative to a nominal value for which the varistor has a very high resistance, are generally used. The varistor is sized to limit (clip) the voltage thereacross to a given value.

A problem is that MOV varistor manufacturing tolerances generate strong dispersions in the turn-on and clipping values.

This makes the selection of the varistors to be used particularly delicate and, most often, results in the discarding of a large number of products.

### SUMMARY

An embodiment aims at overcoming all or part of the disadvantages of usual protection systems based on a single varistor.

An embodiment provides an overvoltage protection device comprising: in series between two terminals intended to be connected to an element to be protected, a varistor and at least one switch; and a circuit for controlling the turning off and the turning on of the switch.

According to an embodiment, the circuit turns on the switch when the voltage between said terminals exceeds a first threshold.

According to an embodiment, said first threshold is set by a break-over component, preferably a zener diode, connecting one of said terminals to a control terminal of the switch.

According to an embodiment, the circuit turns off the switch at the end of a time which follows its turning on.

According to an embodiment, said circuit turns off the switch when the current in the varistor becomes lower than a second threshold.

According to an embodiment, said switch is a GTO thyristor.

According to an embodiment, said switch is a thyristor in series with a MOS transistor.

According to an embodiment, said switch is an IGBT transistor.

According to an embodiment, said first threshold is selected to be lower than the clipping voltage of the varistor, the manufacturing tolerances thereof being taken into account.

An embodiment also provides a system comprising: at least one protection device such as described hereabove; and at least one element to be protected.

An embodiment also provides a DC/AC converter, comprising at least one protection device such as described hereabove.

### BRIEF DESCRIPTION OF THE DRAWINGS

The foregoing and other features and advantages will be discussed in detail in the following non-limiting description of specific embodiments in connection with the accompanying drawings, wherein:

FIG. 1 very schematically shows an example of a system protected by a metal oxide varistor;

FIG. 2 is a simplified electric diagram of an embodiment of a protection device;

FIG. 3 details an embodiment of the control circuit of the device of FIG. 2;

FIG. 4 is a simplified timing diagram illustrating the operation of the assembly of FIG. 3;

FIGS. 5A and 5B are timing diagrams illustrating the operation of the circuit of FIG. 3;

FIG. 6 is a simplified electric diagram of another embodiment of a protection device;

FIGS. 7A and 7B illustrate two alternative embodiments of a switch of the circuit of FIGS. 2 and 6;

FIG. 8 is a simplified electric diagram of an example of application of the protection device; and

FIG. 9 is a simplified electric diagram of an alternative protection device.

### DETAILED DESCRIPTION OF THE DRAWINGS

The same elements have been designated with the same reference numerals in the different drawings. For clarity, only those steps and elements which are useful to the understanding of the described embodiments have been shown and will be detailed. In particular, the components or circuits to be protected by the device have not been detailed, the described embodiments being compatible with any element or component usually protected by a MOV varistor. Further, the DC or AC power supply sources of the element to be protected have not been detailed either, the described embodiments being here again compatible with usual power supply sources.

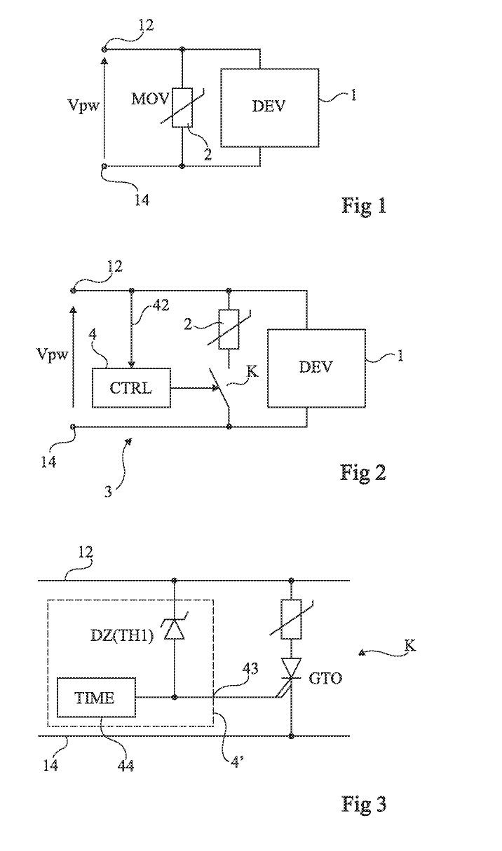

FIG. 1 is a simplified representation of a system formed of an electric or electronic device 1 (DEV), forming an element to be protected by a varistor 2. Element 1 to be protected is connected to two terminals 12 and 14 of application of a power supply voltage Vpw. It is for example the voltage of the electric power distribution system. Varistor 2 of metal oxide type (MOV) connects terminals 12 and 14 and is thus connected in parallel with element 1.

A MOV-type varistor 2 is characterized by a clipping voltage Vcl which should be lower than the maximum voltage that device 1 is capable of withstanding and a nominal voltage Vr which corresponds to the voltage below which the resistivity of the varistor is maximum. Voltages Vr and Vcl define the nominal operating range of the varistor, and a clipping factor which corresponds to ratio Vcl/Vr.

Due to the manufacturing tolerances of MOV-type varistors, this component tends to be undersized in terms of clipping voltage Vcl, to ascertain that it clips at a value lower than the limiting voltage that the device to be protected can withstand, or breakdown voltage. Indeed, voltage Vcl should be lower than the breakdown voltage of the device to be protected. However, the large manufacturing tolerances may result in that, for a given varistor, such a clipping voltage then is in the power supply range of the device to be protected, which then generates losses in terms of normal operation.

FIG. 2 very schematically shows in the form of blocks an embodiment of an overvoltage protection device 3 based on a MOV-type varistor 2. It shows, between terminals 12 and 14 of application of a power supply voltage Vpw, element 1 to be protected. Device 3 comprises a varistor 2, series-connected with a switch K between terminals 12 and 14. Switch K is controlled by a circuit 4 (CTRL) receiving at least one piece of information representative of the voltage between terminals 12 and 14 (connection 42).

Circuit 4 has the function of triggering the turning on and the turning off of switch K so that the varistor is only activated, independently from its real clipping and nominal voltages, during the overvoltage.

It is provided to trigger the turning on of switch K when voltage Vpw exceeds a first threshold TH1. Threshold TH1 is selected to be lower than the breakdown voltage of the element (DEV 1) to be protected but higher than its maximum operating voltage.

It is provided to cause the turning off of switch K to avoid adversely affecting the power supply of the device once the overvoltage has disappeared.

Varistor 2 is preferably selected so that its clipping voltage is, taking into account the maximum manufacturing tolerances, smaller than the breakdown voltage of the device to be protected. For example, if the device to be protected withstands at most 130 volts and the manufacturing tolerance of the varistor is +/−30%, a varistor having a 100-volt clipping voltage Vcl is selected. With a ½ clipping factor, this means that nominal voltage Vr of the varistor may be 50 volts only. As will be seen hereafter, the disconnection of the varistor once the overvoltage has disappeared avoids for this 50-volt value to adversely affect the normal operation of the device.

FIG. 3 is an electric diagram detailing an embodiment of a circuit 4′ for controlling switch K.

According to this embodiment, turn-on threshold TH1 of switch K is set by a zener diode DZ having its anode connected to an output terminal 43 of circuit 4′ intended to be connected to a control terminal of switch K and having its cathode preferably directly connected to terminal 12.

Circuit 4′ further comprises a timing circuit 44 (TIME) in charge of making switch K turn off at the end of a determined time after it turning on by diode DZ.

The example of FIG. 3 assumes a switch K made in the form of a gate turn-on (GTO) thyristor which is thus capable of being turned on when a current flows in its gate through zener diode DZ as soon as threshold voltage TH1 has been reached between terminals 12 and 14 (neglecting the voltage drop between the gate and cathode of the GTO thyristor in the off state). The turning off of the GTO thyristor is obtained by pulling a gate current by means of circuit 44.

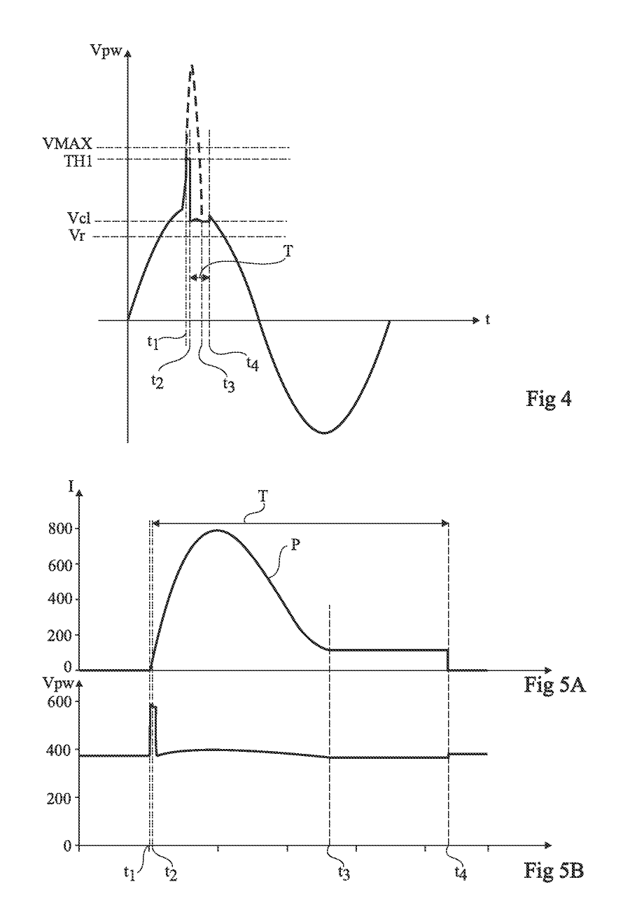

FIG. 4 is a simplified timing diagram illustrating the operation of circuit 4′ of FIG. 3. This drawing shows in exaggerated fashion and in the form of a timing diagram a halfwave of voltage Vpw. An overvoltage (symbolized by a dotted line p) is assumed to occur at a time t₁. When the level of this overvoltage reaches threshold TH1 set by diode DZ, said diode starts conducting and diverts the overvoltage through the gate of the GTO thyristor. When the gate current is sufficient to turn on the thyristor (time t₂), the thyristor turns on, which connects varistor 2 in the circuit. Since the peak voltage is greater than clipping value Vcl of the varistor, said varistor clips the voltage at level Vcl.

At a time t₃, the overvoltage decreases below level Vcl of the varistor. However, it is assumed that the varistor selected with a real clipping voltage Vcl smaller than the maximum normal amplitude of the halfwave (which would be a situation of loss of normal operation in a usual architecture). Thus, the varistor continues to limit the voltage to level Vcl as long as switch K is on. Nominal voltage Vr is at a still lower level.

At the end of a delay T ending at a time t₄, the switch is turned off by circuit 44.

Between times t₃ and t₄, the varistor continues to limit the voltage to level Vcl. This thus results in a lowering of the power supply voltage delivered to element 1. However, this lowering is temporary.

Interval T between times t₂ and t₄ is selected according to the maximum duration of the expected overvoltages.

FIG. 4 illustrates breakdown voltage V_{MAX} of the device to be protected. Threshold TH1 is selected to be lower than this value.

FIGS. 5A and 5B are timing diagrams illustrating a time enlargement at the level of an overvoltage, assumed in this example to be a 2-KV overvoltage. FIG. 5A illustrates the shape of current I in the branch of varistor 2. FIG. 5B illustrates the shape of voltage Vpw between terminals 12 and 14.

At time t₁ of occurrence of the overvoltage, the zener diode, or any other equivalent break-over component, becomes conductive, which causes the turning on of transistor GTO at a time t₂. Overvoltage wave p is then clipped by varistor 2. The overvoltage is assumed to disappear at a time t₃, after which the varistor keeps on clipping the AC voltage until end time t₄ of delay T at which circuit 44 causes the turning off of transistor GTO.

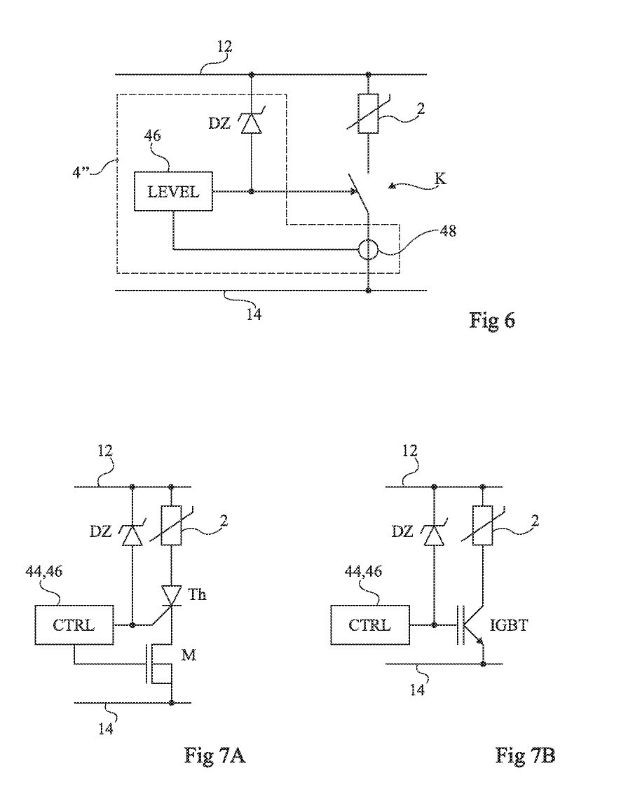

FIG. 6 is an electric diagram of another embodiment of a circuit 4″ for controlling switch K.

According to this embodiment, the turning off of switch K is caused by a circuit 46 (LEVEL) using a measurement of the current in the varistor branch. For example, such a current measurement is obtained by means of a resistor across which the voltage is measured. Different measurement elements or circuits 48 may be used provided that a piece of information, for example, a voltage representative of the current in the branch, is delivered to circuit 46, which compares this current value with a threshold to turn off switch K. It is indeed possible to determine a current in the varistor under which this means that the overvoltage has disappeared and that switch K can be turned off. In the example of FIG. 6, the turn-on element is again a zener diode DZ setting the turn-on voltage threshold.

An advantage of the embodiment of FIG. 6 is that it enables to turn off switch K as early as possible with respect to the disappearing of the overvoltage and avoids the interval between times t₃ and t₄ of the previous embodiment.

FIG. 7A is an electric diagram of an alternative embodiment where switch K is formed of a thyristor Th in series with a MOS transistor M. The thyristor anode is connected to varistor 2. The gate of thyristor Th is connected to the anode of zener diode DZ and to control circuit 4. The gate of transistor M is connected to circuit 44 (or 46). On occurrence of an overvoltage, the current which flows through the zener diode is detected by circuit 44 (or 46). In practice, the voltage increase of the anode of the zener diode may be detected to turn on MOS transistor M. The current in the zener diode then flows through the gate of thyristor Th and then into MOS transistor M to turn on thyristor Th. To turn off the switch, the current has to be suppressed in the thyristor. This is achieved by means of circuit 44 (or 46) which turns off of transistor M, either at the end of a predetermined time in the embodiment of FIG. 4, or when a detection element, not shown in FIG. 7A, detects that the current in the varistor becomes lower than a threshold.

FIG. 7B illustrates another variation where switch K is formed of an IGBT transistor having its gate connected to the anode of the zener diode and to circuit 44 (or 46). An IGBT transistor can be turned off and on by varying the voltage applied to its gate.

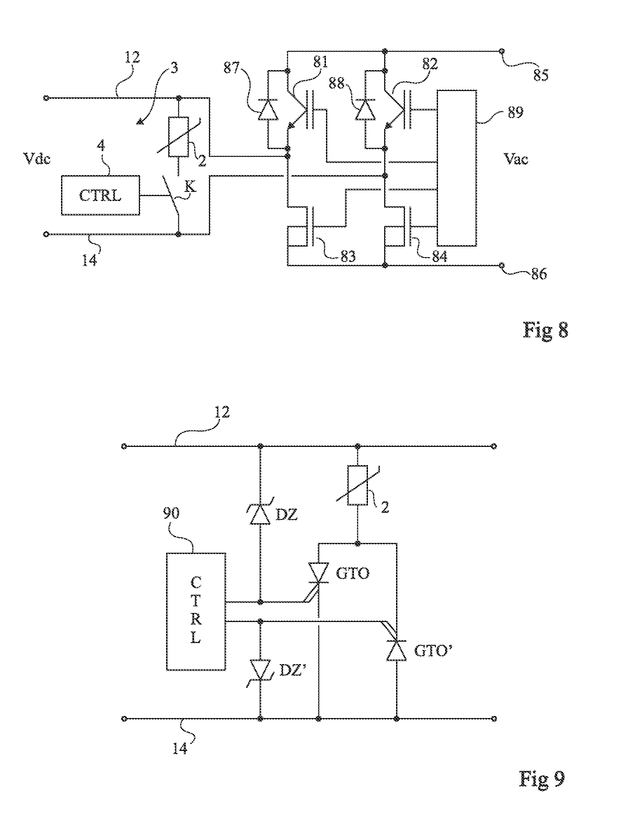

FIG. 8 is a simplified representation of an example of application to a DC/AC power converter of the inverter type, formed of IGBT transistors 81 and 82 in series with MOS transistors 83 and 84, in two parallel branches between two output terminals 85 and 86 delivering an AC voltage Vac. A diode 87, respectively 88, is assembled in parallel with transistor 81, respectively 82, to provide the flowing of the current when the IGBT transistor is off and the current flows in the reverse direction (the corresponding MOS transistor being on). The junction points of the IGBT and MOS transistors are connected to terminals 12 and 14 of application of a DC voltage Vdc having a protection device 3 such as described hereabove connected therebetween. The gates of transistors 81 to 84 are connected to a control circuit 89 synchronizing the conduction periods according, for example, to the halfwaves of AC voltage Vac and to the needs of the load (not shown) connected to terminals 85 and 86. Such a power converter taken as an example has a continuous operation. It for example is an inverter for converting the energy delivered by a source of photovoltaic type to inject it back into the electric distribution system. The network is sensitive to overvoltages due, for example, to lightning, which justifies the need to protect the converter components.

In the case of a three-phase power supply, the protections are generally provided between each phase and the neutral and between the phases two by two.

The protection device may also be used to protect an element powered with a DC voltage.

To clip positive and negative overvoltages with respect to a reference potential, typically the ground or earth, protection device 3 may be duplicated by connecting the zener diode to terminal 14 (anode on the side of terminal 14). However, the varistor being bidirectional, it may also be shared for both disturbance directions.

FIG. 9 shows an alternative embodiment of the protection device capable of clipping positive and negative voltages with respect to a reference voltage, typically the ground or earth, by means of a single varistor 2. In this example, two one-way switches (for example, two thyristors GTO and GTO′), assembled in antiparallel with respect to each other and in series with varistor 2, are used. In other words, one of the thyristors, for example, thyristor GTO, has its anode connected to the varistor (the other terminal thereof being connected to terminal 12) and its cathode connected to terminal 14 while the other in this example, thyristor GTO′, has its anode connected to terminal 14 and its cathode connected to the varistor. The thyristor gates are connected to a control circuit 90 (CTRL) reproducing the functions of two circuits 44 or of two circuits 46. The gate of thyristor GTO is connected by a first zener diode DZ to terminal 12. The gate of thyristor GTO′ is connected, by a second zener diode DZ′, to terminal 14, the cathode of diode DZ′ being connected to terminal 14.

An advantage of the described embodiments is that, due to the disconnection of the varistor when the overvoltage has disappeared, it is now possible to use a varistor having its clipping value ensuring a protection of the device even if its nominal value is lower than the normal operating voltage of the device.

Various embodiments and variations have been described. It should be noted that those skilled in the art may combine various elements of these various embodiments and variations without showing any inventive step. Further, various alterations, modifications, and improvements will occur to those skilled in the art. In particular, the selection of the varistor and the sizing of the various components of the control circuit depend on the voltage levels acceptable by the element to be protected. Further, the zener diodes may be replaced with any adapted break-over component, for example, transient voltage suppression diodes (TVS), also known as Transil diodes. Further, the practical forming of the timing circuits and of the circuit for comparing the current with a threshold are within the abilities of those skilled in the art based on the functional indications given hereabove and using components usual per se.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An overvoltage protection device, comprising:
a varistor;
at least one switch;
wherein the varistor and switch are coupled in series between first and second terminals configured to be connected to a circuit element to be protected; and
a circuit configured to control turning off and turning on of the switch in response to a voltage across said first and second terminals.

2. The device of claim 1, wherein the circuit is configured to turn on the switch when the voltage across said first and second terminals exceeds a first threshold.

3. The device of claim 2, wherein said circuit includes a break-over component configured to set said first threshold.

4. The device of claim 3, wherein the break-over component comprises a zener diode coupled between one of said first and second terminals and a control terminal of the switch.

5. The device of claim 1, wherein said circuit is configured to turn off the switch at the end of a time delay, wherein said time delay start when said switch is turned on.

6. The device of claim 1, wherein said circuit is configured to turn off the switch when current in the varistor becomes less than a second threshold.

7. The device of claim 1, wherein said switch is a gate turn on (GTO) thyristor.

8. The device of claim 1, wherein said switch is a thyristor coupled in series with a metal oxide semiconductor (MOS) transistor.

9. The device of claim 1, wherein said switch is an insulated gate bipolar transistor (IGBT).

10. The device of claim 1, wherein said switch comprises:
a first gate turn on (GTO) thyristor; and
a second GTO thyristor;
wherein the first and second GTO thyristers are coupled in antiparallel with each other and in series with the varistor.

11. The device of claim 10, wherein the circuit comprises:
a first zener diode coupled between the first terminal an a control terminal of the first GTO thyrister; and
a second zener diode coupled between the second terminal an a control terminal of the second GTO thyrister.

12. The device of claim 1, wherein said circuit comprises:
a current sensor coupled in series with the switch and said varistor; and
circuitry responsive to said current sensor and the voltage across said first and second terminals configured to actuate said switch when the voltage exceeds a first threshold and deactuate said switch when the sensed current is less than a second threshold.

13. The device of claim 2, wherein said first threshold is lower than a clipping voltage of the varistor.

14. The device of claim 1, wherein the circuit element to be protected is a DC/AC converter circuit.

15. A method, comprising:
sensing voltage on a first conductor supplying power to a device to be protected against overvoltage; and
connecting a varistor in a circuit between the first conductor and the second conductor if the sensed voltage on the first conductor is in excess of a supply voltage for said device to be protected but less than a clipping voltage of the varistor.

16. The method of claim 15, further comprising sensing current flow in said circuit and disconnecting the varistor from said circuit when the current reaches a threshold.

17. The method of claim 15, further comprising disconnecting the varistor from said circuit following expiration of a time delay.
